(19) United States
(12) Patent Application Publication
(10) Pub. No.: US 2025/0240995 A1
(43) Pub. Date: Jul. 24, 2025

(54) METHOD OF MANUFACTURING VERTICAL DEVICE BY FIRSTLY ETCHING ACTIVE REGION OF DEVICE

(71) Applicants: BEIJINGSUPERSTRIN ACADEMY OF MEMORY TECHNOLOGY, Beijing (CN); Institute of Microelectronics, Chinese Academy of Sciences, Beijing (CN)

(72) Inventors: Wenliang LIU, Beijing (CN); Yongkui ZHANG, Beijing (CN); Yong DU, Beijing (CN)

(73) Assignees: BEIJINGSUPERSTRIN ACADEMY OF MEMORY TECHNOLOGY, Daxing District (CN); Institute of Microelectronics, Chinese Academy of Sciences, Beijing (CN)

(21) Appl. No.: 18/774,635

(22) Filed: Jul. 16, 2024

(30) Foreign Application Priority Data
Jan. 18, 2024 (CN) 202410074589.3

(51) Int. Cl. H01L 29/66; H01L 21/3065; H01L 21/308

(52) U.S. Cl. CPC H10D 30/025; H01L 21/3065; H01L 21/308

(57) ABSTRACT

The present disclosure provides a method of manufacturing a vertical device by firstly etching an active region of the device, which may be applied to the field of semiconductor technology. The method includes: providing a stack of a first source/drain defining layer, a channel defining layer and a second source/drain defining layer on a substrate; providing a mask layer on the stack; providing a patterned photoresist on the stack, where the patterned photoresist exposes a first region; etching off, in the first region, a first depth of the stack based on the patterned photoresist; and further etching off, in the first region and a second region on an inner side of the first region, a second depth of the stack based on the mask layer, where the stack is penetrated by the etching off and the further etching off in the first region to form an isolation trench.

### CROSS REFERENCE TO RELATED APPLICATION

This application claims priority to Chinese Patent Application No. 202410074589.3, filed on Jan. 18, 2024, the entire content of which is incorporated herein in its entirety by reference.

### TECHNICAL FIELD

The present disclosure relates to the field of semiconductor technology, and in particular to a method of manufacturing a vertical device by firstly etching an active region of the device.

### BACKGROUND

In order to meet requirements of increasing miniaturization of semiconductor devices, various device structures have been proposed, such as fin field-effect transistor (FinFET), multi-bridge-channel field-effect transistor (MBCFET), saddle-fin field-effect transistor (Saddle-Fin FET), and so on. However, these device structures still have some limitations.

Vertical FET is an MOSFET that has a promising prospect in terms of miniaturization. However, the vertical FET has a large height difference in a vertical direction, and the height difference may far exceed a coverage capacity of a photoresist, especially as the number of stacked layers increases.

### SUMMARY

The present disclosure provides a method of manufacturing a vertical device by firstly etching an active region of the device.

In a first aspect of the present disclosure, a method of manufacturing a vertical device by firstly etching an active region of the device is provided, including: providing a stack of a first source/drain defining layer, a channel defining layer and a second source/drain defining layer on a substrate; providing a mask layer on the stack; providing a patterned photoresist on the stack, where the patterned photoresist exposes a first region; etching off, in the first region, a first depth of the stack based on the patterned photoresist; and further etching off, in the first region and a second region on an inner side of the first region, a second depth of the stack based on the mask layer, where the stack is penetrated by the etching off and the further etching off in the first region to form an isolation trench.

### BRIEF DESCRIPTION OF THE DRAWINGS

The above and other objectives, features and advantages of the present disclosure will be more apparent through the following description of the embodiments of the present disclosure with reference to the accompanying drawings. In the accompanying drawings:

FIG. 1 to FIG. 30 schematically show some stages in a process of manufacturing a semiconductor device according to the embodiments of the present disclosure, in which:

FIG. 5(a), FIG. 8(a) and FIG. 28(a) show top views, where a position of line AA′ is shown in FIG. 5(a); and

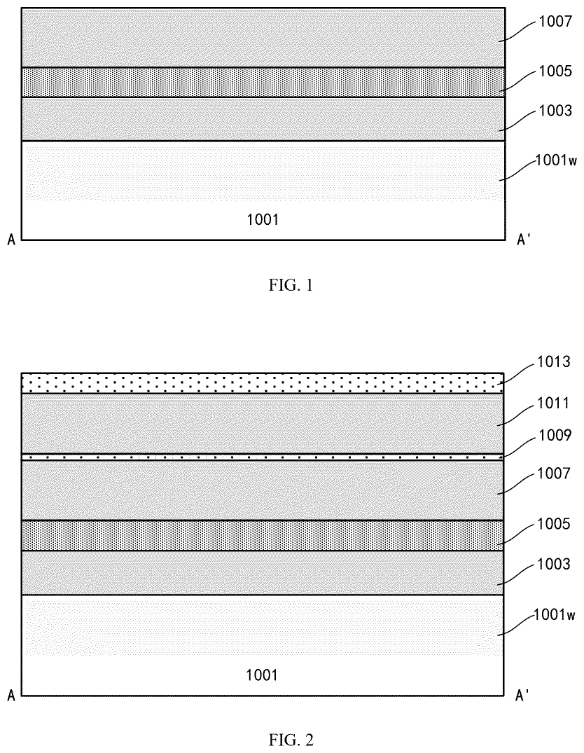

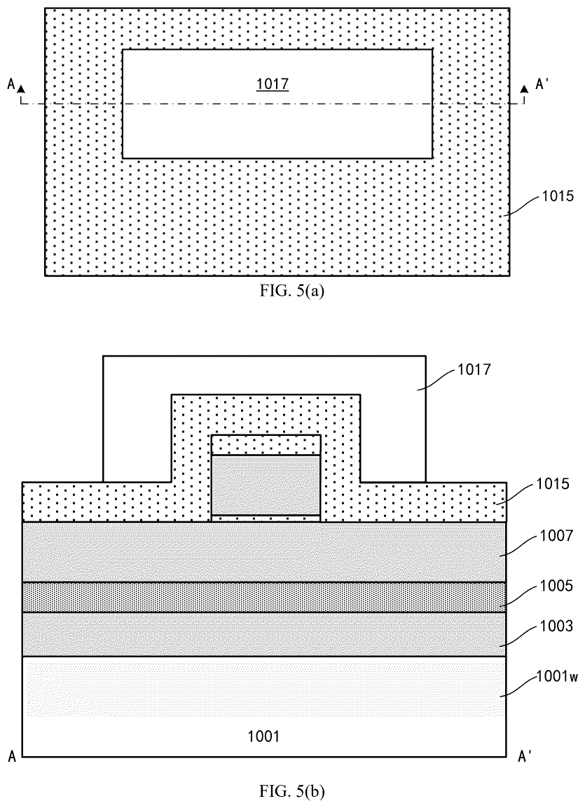

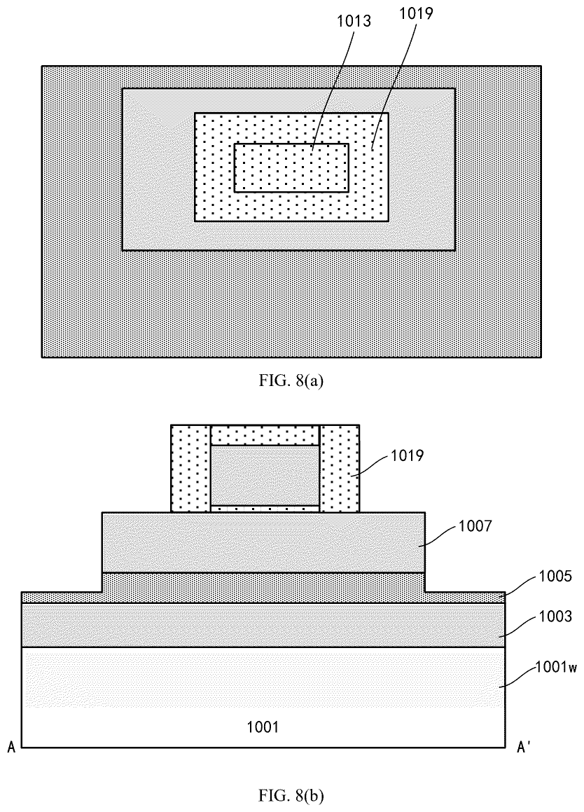

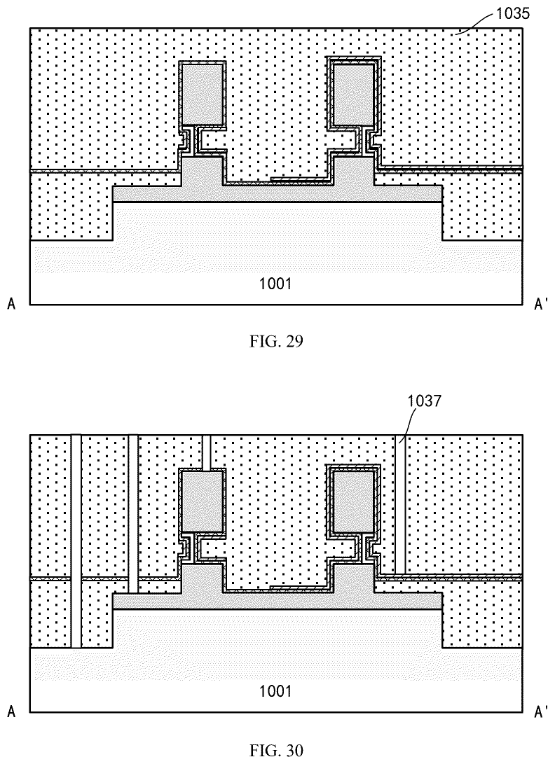

FIG. 1 to FIG. 4, FIG. 5(b) to FIG. 7, and FIG. 8(b) to FIG. 30 show cross-sectional views taken along line AA′.

Throughout the accompanying drawings, the same or similar reference numbers may denote the same or similar components. The accompanying drawings are not necessarily drawn to scale. Especially, for clarity, cross-sectional views are drawn at different scales from top views.

### DETAILED DESCRIPTION OF EMBODIMENTS

Embodiments of the present disclosure will be described below with reference to the accompanying drawings. It should be understood, however, that these descriptions are just exemplary and are not intended to limit the scope of the present disclosure. In addition, in the following, descriptions of well-known structures and technologies are omitted to avoid unnecessarily obscuring the concepts of the present disclosure.

Various schematic structural diagrams according to the embodiments of the present disclosure are shown in the accompanying drawings. These drawings are not drawn to scale. Some details are enlarged and some details may be omitted for clarity of presentation. The shapes of the various regions and layers as well as the relative size and positional relationship thereof shown in the drawings are just exemplary. In practice, there may be deviations due to manufacturing tolerances or technical limitations, and those skilled in the art may additionally design regions/layers with different shapes, sizes and relative positions according to actual needs.

In the context of the present disclosure, when a layer/element is referred to as being located “on” a further layer/element, the layer/element may be located directly on the further layer/element, or there may be an intermediate layer/element between them. In addition, if a layer/element is located “on” a further layer/element in one orientation, the layer/element may be located “under” the further layer/element when the orientation is reversed.

The present disclosure may be presented in various forms, some examples of which will be described below. A selection of various materials is involved in the following descriptions. In the selection of materials, in addition to functions of the materials (for example, a semiconductor material may be used to form an active region, and a dielectric material may be used to form an electrical isolation, etc.), an etching selectivity is also considered. In the following descriptions, a required etching selectivity may or may not be indicated. It should be clear to those skilled in the art that when etching a material layer is mentioned below, if it is not mentioned or shown that other layers are also etched, then the etching may be selective, and the material layer may have an etching selectivity relative to other layers exposed to a same etching formula.

FIG. 1 to FIG. 30 schematically show some stages in a process of manufacturing a semiconductor device according to the embodiments of the present disclosure.

As shown in FIG. 1, a substrate 1001 is provided. The substrate 1001 may be in various forms, including but not limited to a bulk semiconductor material substrate such as a bulk silicon (Si) substrate, a semiconductor-on-insulator (SOI) substrate, a compound semiconductor substrate such as a SiGe substrate, and the like. In the following descriptions, for the sake of explanation, a bulk Si substrate is taken as an example for description. Here, a silicon wafer is provided as the substrate 1001.

In the substrate 1001, a well region 1001w may be formed by, for example, an ion implantation. The well region 1001w may contain a dopant of a particular conduction type (e.g., a p-type conduction for an n-type device, or an n-type conduction for a p-type device) and a particular concentration. The well region may be provided in various manners in the art, which will not be described in detail here.

On the substrate 1001, a first source/drain defining layer 1003, a channel defining layer 1005 and a second source/drain defining layer 1007 may be formed sequentially by, for example, epitaxial growth. The layers grown on the substrate 1001 may be single-crystal semiconductor layers and may have crystal interfaces therebetween.

The first source/drain defining layer 1003 and the second source/drain defining layer 1007 may subsequently define a position of a source/drain region. The first source/drain defining layer 1003 and the second source/drain defining layer 1007 may be doped with a dopant having a particular conduction type (e.g., an n-type conduction for an n-type device, or a p-type conduction for a p-type device) and a particular concentration, for example, by in-situ doping during growth.

The first source/drain defining layer 1003, the channel defining layer 1005 and the second source/drain defining layer 1007 may contain various suitable semiconductor materials, e.g., an elemental semiconductor material such as Si or Ge, or a compound semiconductor material such as SiGe, etc. In order to provide appropriate etching selectivity in subsequent processes, adjacent layers in these layers may have etching selectivity between each other. For example, the first source/drain defining layer 1003 and the second source/drain defining layer 1007 may contain Si, while the channel defining layer 1005 may contain SiGe. The channel defining layer 1005, the first source/drain defining layer 1003 and the second source/drain defining layer 1007 may be formed by, for example, epitaxial growth, and thus may contain a single crystal material.

In order to avoid photolithography limitations, Spacer Image Transfer technology is used in the following patterning according to the embodiments of the present disclosure. A mandrel pattern may be formed to form a spacer. For example, as shown in FIG. 2, a mandrel layer 1011 may be formed on the second source/drain defining layer 1007 by, for example, deposition such as chemical vapor deposition (CVD). For example, the mandrel layer 1011 may contain a-Si. In addition, for a better etching control, an etching stop layer 1009 may be formed firstly by, for example, deposition such as CVD. For example, the etching stop layer 1009 may contain an oxide.

On the mandrel layer 1011, an upper hard mask layer 1013 may be formed by, for example, deposition such as CVD. For example, the upper hard mask layer 1013 may contain an oxide.

As shown in FIG. 3, (the upper hard mask layer 1013 and) the mandrel layer 1011 may be patterned into a mandrel pattern by an anisotropic etching, such as reactive ion etching (RIE) in a vertical direction (referring to the top view in FIG. 8(a)). The etching of the mandrel layer 1011 may stop at the etching stop layer 1009, and the etching stop layer 1009 exposed therefrom may be etched.

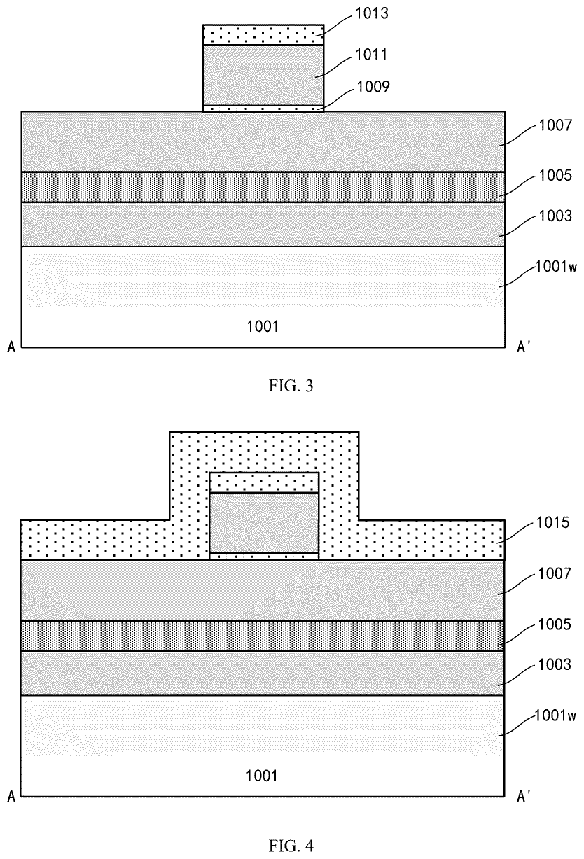

As shown in FIG. 4, a preparatory spacer layer 1015 may be formed in a substantially conformal manner on the etching stop layer 1009 by, for example, deposition such as CVD. The etching stop layer 1009, the mandrel layer 1011, the upper hard mask layer 1013 and the preparatory spacer layer 1015 (or a spacer obtained therefrom) may be used in subsequent processes to assist in patterning, and may therefore be collectively referred to as a mask layer. Depending on the patterning process, the mask layer may be formed by different numbers of layers and/or different materials.

Interfaces between the preparatory spacer layer 1015, the upper hard mask layer 1013 and the etching stop layer 1009 are shown in the figures in order to clearly illustrate positions of the three (to facilitate understanding of readers). It should be noted that the three are all oxides in this example.

As shown in FIG. 5(a) and FIG. 5(b), a photoresist 1017 may be formed on the preparatory spacer layer 1015 and patterned by photolithography into a shape corresponding to an active region to be defined. In an illustrated example, the patterned photoresist 1017 is patterned into a rectangle. However, the present disclosure is not limited to this. For example, the photoresist 1017 may be patterned into other suitable shapes, such as a square, a circle, an ellipse, etc.

Here, the patterned photoresist 1017 is formed on the preparatory spacer layer 1015. A top surface of the preparatory spacer layer 1015 may have a rise and fall (e.g., a step shape) and thus have a particular height difference of, e.g., about 0.7 μm (or less). The height difference is less than a height of an entire stack of the vertical device, so that a requirement for a coverage capability of the photoresist may be reduced.

The patterned photoresist 1017 may expose a first region. For example, a region exposed by the photoresist 1017 in the top view of FIG. 5(a) may be a range of the first region.

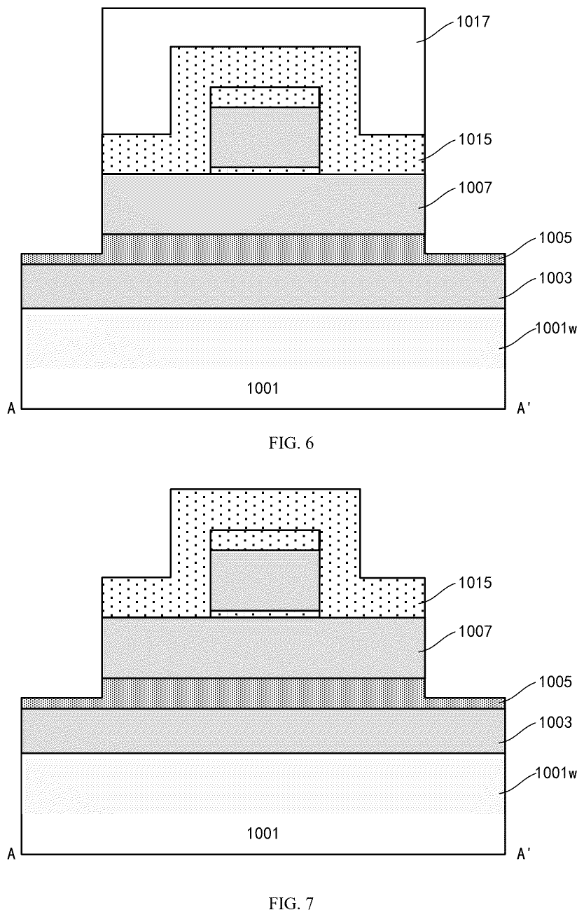

Using the photoresist 1017 as an etching mask, a first depth of the stack may be etched off in the first region by, for example, reactive ion etching (RIE). For example, as shown in FIG. 6, the preparatory spacer layer 1015, the second source/drain defining layer 1007 and the channel defining layer 1005 may be etched by RIE in the vertical direction. In this example, the etching may stop in the channel defining layer 1005. After that, the photoresist 1017 may be removed, as shown in FIG. 7. It may be understood that the first depth is not limited to this, and the first depth may be also in the second source/drain defining layer 1007 or the first source/drain defining layer 1003 of the stack.

As shown in FIG. 8(a) and FIG. 8(b), an anisotropic etching such as RIE may be performed on the preparatory spacer layer 1015 in the vertical direction, so as to remove a laterally extending portion of the preparatory spacer layer 1015 and leave a vertically extending portion of the preparatory spacer layer 1015, thereby obtaining a spacer 1019. The upper hard mask layer 1013 on the mandrel layer 1011 may be retained. In addition to exposing the first region (as described above with reference to FIG. 5(a)), the spacer 1019 and the mandrel layer 1011 (or the upper hard mask layer 1013 thereon) may further expose a second region on an inner side of the first region (the second region may be a region previously covered by the patterned photoresist 1017 on an outside of the spacer 1019). Moreover, the spacer 1019 may also extend on a sidewall of the upper hard mask layer 1013 and a sidewall of the etching stop layer 1009.

Interfaces between the spacer 1019, the upper hard mask layer 1013 and the etching stop layer 1009 are shown in the figures in order to clearly illustrate positions of the three (to facilitate understanding of readers). It should be noted that the three are all oxides in this example.

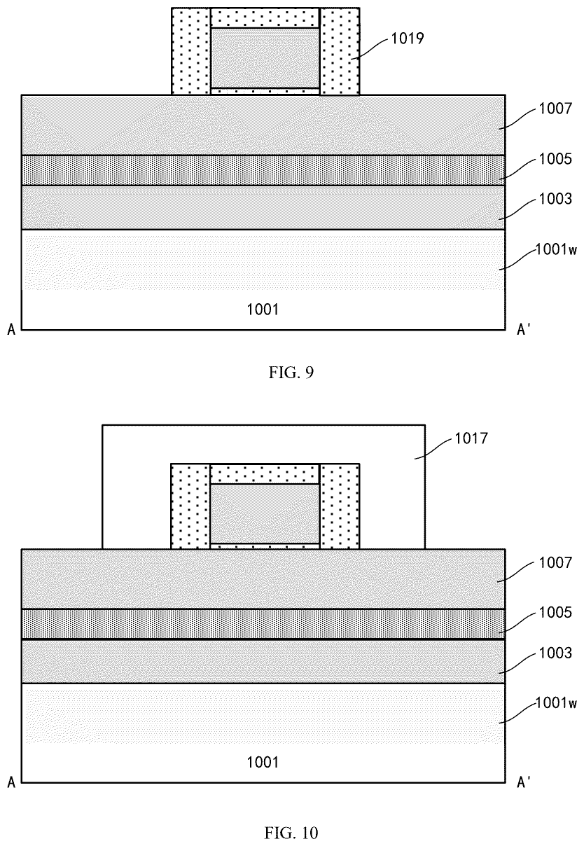

In the above-mentioned embodiment, a first etching is performed before the formation of the spacer 1019. However, the present disclosure is not limited to this. According to another embodiment of the present disclosure, the first etching may be performed after the formation of the spacer 1019. As shown in FIG. 9, a preparatory spacer layer (referring to the above descriptions with reference to FIG. 4) may be formed, and the preparatory spacer layer may be formed into a spacer 1019 by anisotropic etching (referring to the above descriptions with reference to FIG. 8(a) and FIG. 8(b)).

As shown in FIG. 10, after the formation of the spacer 1019, a patterned photoresist 1017 may be formed on the second source/drain defining layer 1007. Similarly, a height difference covered by the patterned photoresist 1017 may be about 0.7 μm (or less).

As described above with reference to FIG. 6, using the photoresist 1017 as an etching mask, the first depth of the stack may be etched off in the first region. After that, the photoresist 1017 may be removed. A structure thus obtained is identical to the structure shown in FIG. 8(a) and FIG. 8(b). Based on this structure, the stack may be further etched to form an isolation trench.

According to the embodiments of the present disclosure, as shown in FIG. 11, a second depth of the stack may be further etched off in the first region and the second region that are exposed by the spacer 1019 and the upper hard mask layer 1013. Specifically, using the upper hard mask layer 1013 and the spacer 1019 as an etching mask, the second depth of the stack may be etched off in the first region and the second region by, for example, reactive ion etching (RIE). In the first region, the etching may enter the substrate 1001, so that the stack is penetrated by etching to form an isolation trench (e.g., a shallow trench isolation (STI) trench).

Furthermore, in the second region, the etching may enter the first source/drain defining layer 1003, but does not reach a bottom of the first source/drain defining layer 1003. Accordingly, the first source/drain defining layer 1003 may have a protruding portion relative to the active layer located above, for a subsequent fabrication of a contact portion of a source/drain region formed therein.

Here, the first depth and the second depth may be designed properly so that a sum of the first depth and the second depth may ensure the formation of the isolation trench in the first region (because the sum of the first depth and the second depth of the stack is etched off in the first region), and the second depth may ensure the formation of the above morphology in the second region (because the second depth of the stack is etched off in the second region).

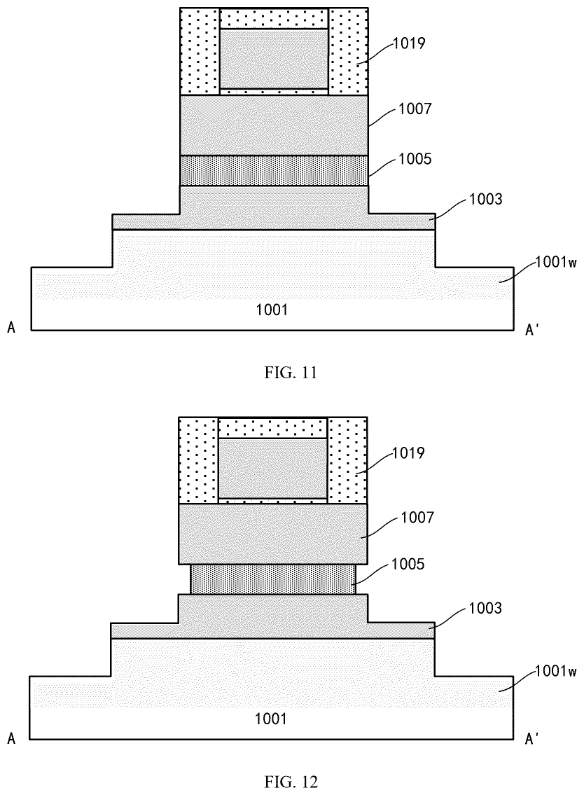

A space between the first source/drain defining layer 1003 and the second source/drain defining layer 1007 may be released, so that a gate stack subsequently formed may be (at least partially) provided in the space to be self-aligned with a channel portion defined by the channel defining layer 1005. As shown in FIG. 12, the channel defining layer 1005 may be selectively etched so that a sidewall of the channel defining layer 1005 is relatively recessed in a lateral direction (e.g., a horizontal direction on a paper surface in FIG. 12) to form a recess portion. The etching may be isotropic dry or wet etching.

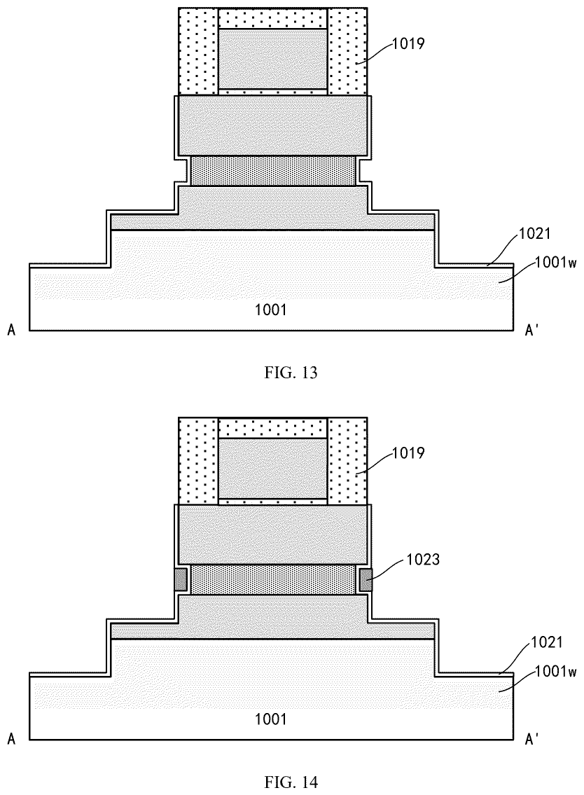

According to the embodiments of the present disclosure, as shown in FIG. 13, an active layer 1021 may be formed by epitaxial growth. Selective epitaxial growth may be used so that the active layer 1021 may be formed only on a surface of the semiconductor material. A portion of the active layer 1021 on a sidewall of the channel defining layer 1005 may then face the gate stack and thus define the channel portion. As the channel portion extends substantially in the vertical direction, the active layer 1021 (in particular the portion of the active layer 1021 on the sidewall of the channel defining layer 1005) may also be referred to as a (vertical) channel layer.

A silicon material is taken as an example here in describing the active layer 1021. However, the present disclosure is not limited to this. The material of the active layer 1021 may be appropriately selected according to performance requirements of the design for the device. For example, the active layer 1021 may contain various semiconductor materials, e.g., an elemental semiconductor material such as Ge, etc., or a compound semiconductor material such as SiGe, InP, GaAs, InGaAs, etc.

To prevent subsequent processing from affecting the active layer 1021, a protective layer may be formed to protect the active layer 1021. For example, as shown in FIG. 14, a protective layer 1023 may be formed in a space released at an end portion of the channel defining layer 1005 (after the channel layer is formed). For example, the protective layer 1023 may be formed by deposition followed by etching back, and may contain a dielectric material such as SiN or a variety of composite film layer structures.

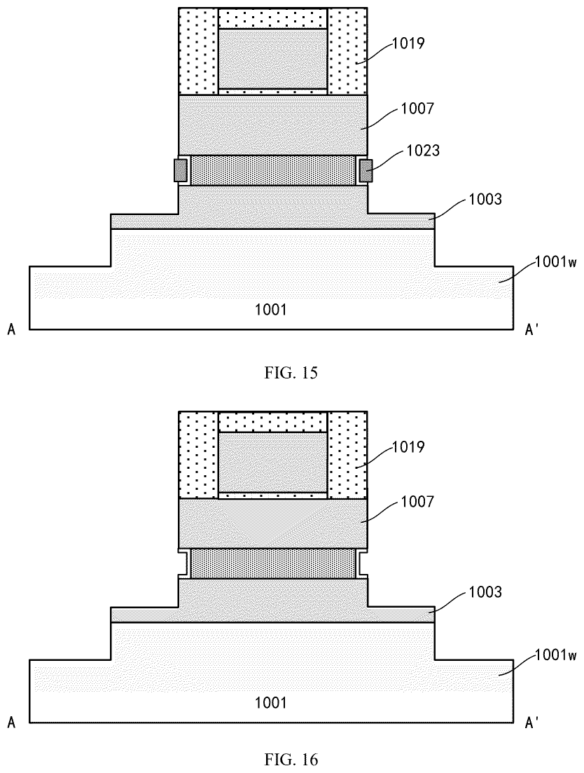

Currently, the active layer 1021 extends into the isolation trench in the first region. As shown in FIG. 15, an isotropic etching may be performed on the active layer 1021 to confine the active layer 1021 in the active region. After that, the protective layer 1023 may be removed, as shown in FIG. 16.

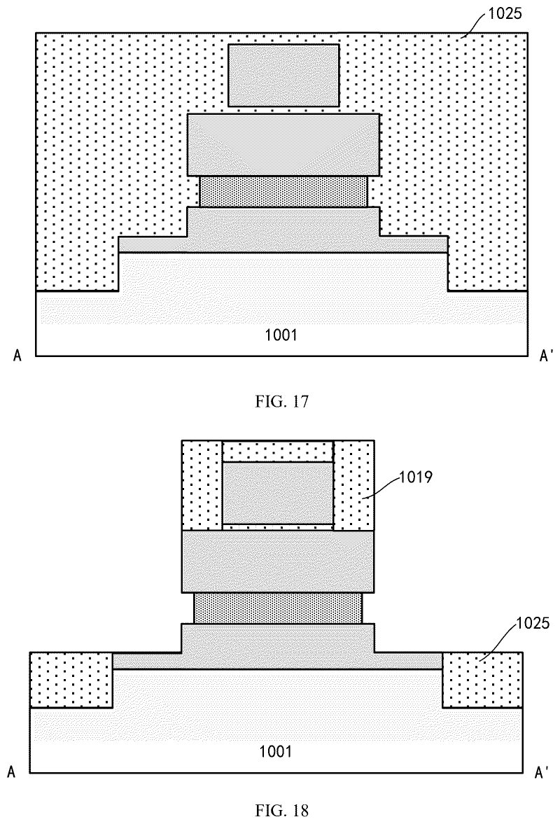

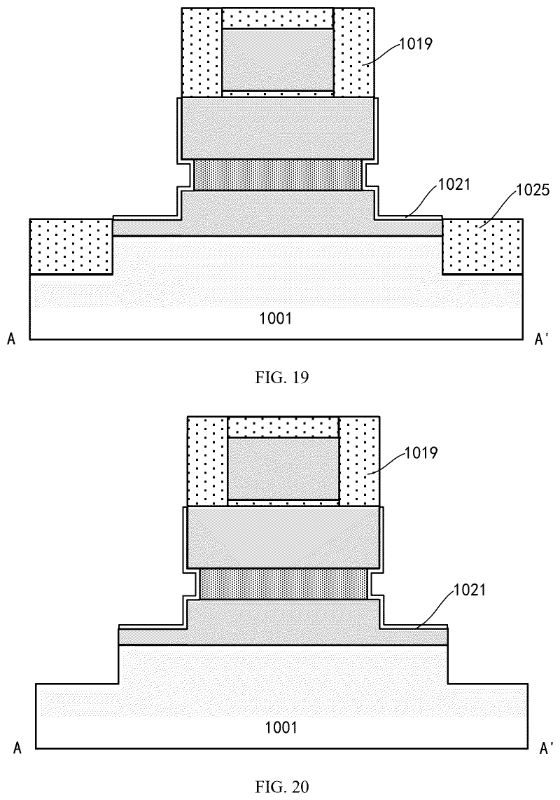

In the above-mentioned embodiment, after the active layer 1021 is formed, a step of etching the active layer 1021 is performed, which may affect a quality of the active layer 1021. According to another embodiment of the present disclosure, the isolation trench may be filled with dielectric firstly to avoid the active layer 1021 being formed in the isolation trench. For example, as shown in FIG. 17, a first dielectric layer 1025 may be formed on the substrate 1001 by, for example, deposition. For example, the first dielectric layer 1025 may contain an oxide. For convenience, the etching stop layer 1009, the spacer 1017 and the upper hard mask layer 1013, which are oxides, are shown as a whole in the figure. Then, the deposited first dielectric layer 1025 may be planarized by chemical mechanical polishing (CMP), and the planarized first dielectric layer 1025 may be etched back, so that the first dielectric layer 1025 remains in the isolation trench in the first region, as shown in FIG. 18. Then, as shown in FIG. 19, the active layer 1021 may be formed by selective epitaxial growth. After that, the first dielectric layer 1025 may be removed, and a structure shown in FIG. 20 may be obtained. Here, it is not required to further etch the active layer 1021 after the growth of the active layer 1021. The structure of FIG. 20 is similar to that of FIG. 16, except that the active layer 1021 extends to a larger range in the active region. The structure of FIG. 16 is illustrated below by way of example in describing subsequent processes.

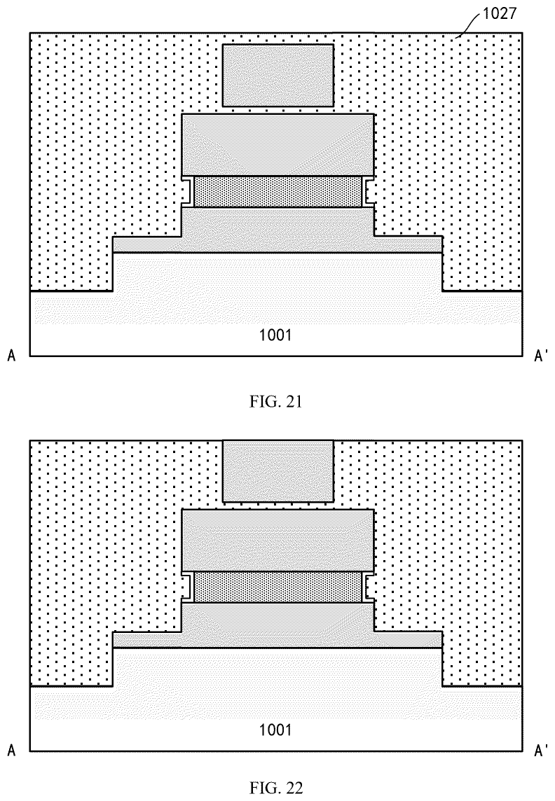

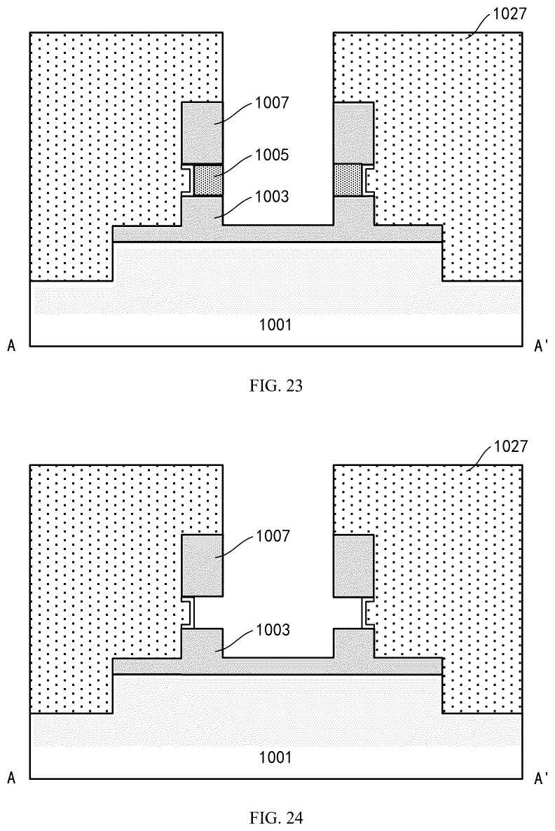

As shown in FIG. 21, a second dielectric layer 1027 may be formed on the substrate 1001. For example, the second dielectric layer 1027 may contain an oxide. Then, as shown in FIG. 22, the deposited oxide may be planarized by chemical mechanical polishing (CMP), where the CMP may stop at the mandrel layer 1011.

As shown in FIG. 23, the mandrel layer 1011 may be removed by selective etching, such as wet etching using TMAH solution (stopping at the etching stop layer 1009). Accordingly, an opening (corresponding to a region surrounded by the spacer 1019 which is a closed ring) is formed in the second dielectric layer 1027. Via this opening, the etching stop layer 1009, the second source/drain defining layer 1007, the channel defining layer 1005 and the first source/drain defining layer 1003 may be selectively etched sequentially by, for example, RIE in the vertical direction. An etching depth of the first source/drain defining layer 1003 on an inner side of the spacer 1019 may be substantially the same as an etching depth of the first source/drain defining layer 1003 on an outer side of the spacer 1019. Accordingly, below the original spacer 1019 (now shown as integrated with the second dielectric layer 1027), the second source/drain defining layer 1007, the channel defining layer 1005, an upper portion of the first source/drain defining layer 1003, and the active layer 1017 are formed into a closed ring corresponding to the spacer 1019.

Currently, an inner side of the active layer 1021 is covered by the channel defining layer 1005. As shown in FIG. 24, the channel defining layer 1005 may be removed by selective etching, so as to leave a space for a gate stack on the inner side of the active layer 1021.

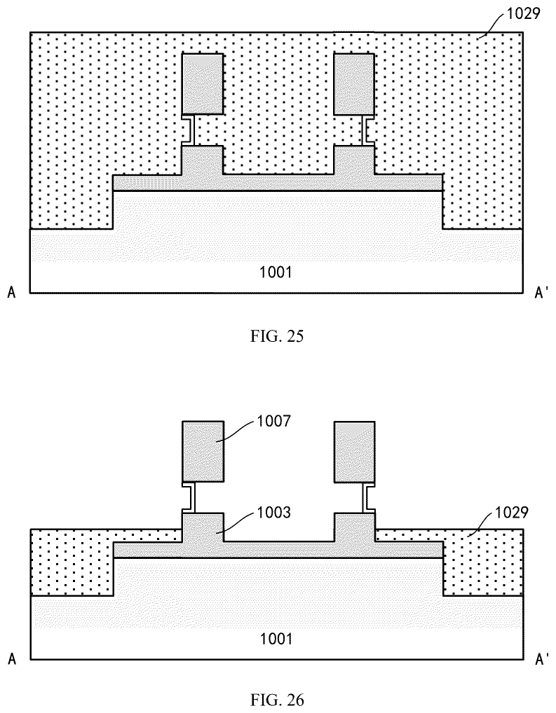

As shown in FIG. 25, an oxide may be deposited on the substrate 1001, and the deposited oxide may be planarized by CMP to form a third dielectric layer 1029 (along with the previous second dielectric layer 1027). As shown in FIG. 26, a certain depth of the third dielectric layer 1029 may be etched off by, for example, wet etching. A surface of the etched third dielectric layer 1029 may be lower than a top surface of the first source/drain defining layer 1003, so that a gate stack subsequently formed thereon may intersect with an entire height of the channel layer.

In this way, a definition of the active region, especially the source/drain region and the channel portion therein, is completed. A gate stack may be formed on such defined active region to complete the device manufacturing.

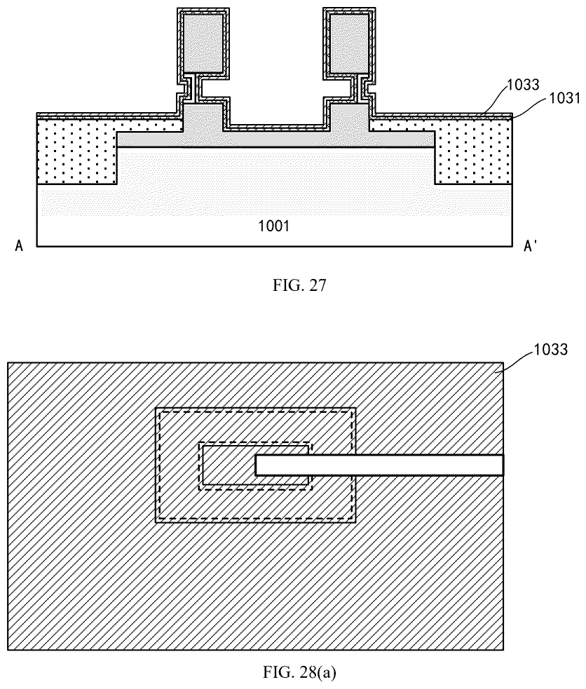

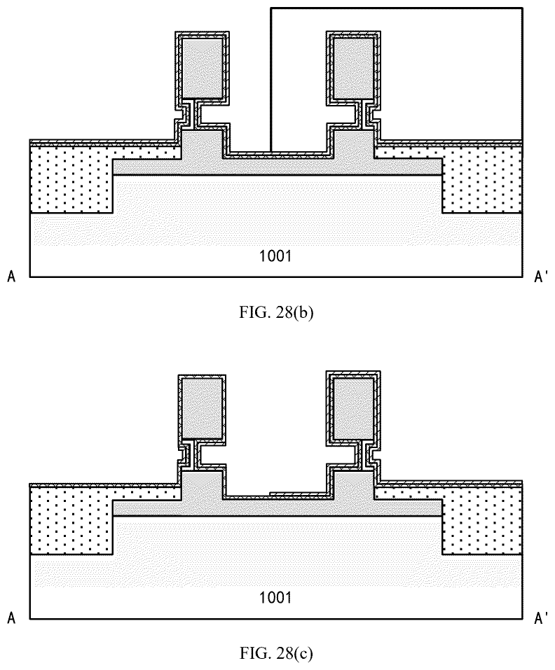

For example, as shown in FIG. 27, a gate stack may be formed. The gate stack may include a gate dielectric layer 1031 and a gate electrode layer 1033 stacked sequentially. Here, the gate dielectric layer 1031 and the gate electrode layer 1033 are formed in a substantially conformal manner. As shown in FIG. 28(a) to FIG. 28(c), the gate electrode layer 1033 thus formed may be selectively etched. A photoresist may be formed on the gate electrode layer 1033, and may be patterned by photolithography to cover a portion of the gate electrode layer 1033. The photoresist may be patterned to cover a partial region where the original spacer 1019 is located (to cover the gate stack therein), and extend a particular range from that region. In the illustrated example, the photoresist is shown as a rectangle. However, the present disclosure is not limited to this, and the photoresist may be patterned as any other shape suitable for manufacture. A fourth dielectric layer 1035 may be formed on the substrate by, for example, deposition followed by planarization. A contact hole may then be formed, and the contact hole may be filled with a conductive material such as metal to form a contact portion 1037. The contact portion 1037 may include a contact portion penetrating the fourth dielectric layer 1035 to connect to the second source/drain defining layer 1007, a contact portion penetrating the fourth dielectric layer 1035 to connect to the first source/drain defining layer 1003, a contact portion penetrating the fourth dielectric layer 1035 to connect to a landing pad of the gate electrode, and a contact portion penetrating the fourth dielectric layer 1035 to connect to the well region. It may be understood that in addition to the methods of forming the contact portions of the vertical device provided in the present disclosure, various other methods in the art may also be used to form the contact portions of the vertical device, which will not be described in detail here.

After that, the subsequent processes may be performed, which will not be described in detail here.

According to the embodiments of the present disclosure, by providing a mask layer and providing a patterned photoresist before etching, it is avoided that the photoresist needs to cover a too large height in the vertical device, so that an ability of etching the active region of the vertical device is improved.

The semiconductor device according to the embodiments of the present disclosure may be applied to various electronic apparatuses. Accordingly, the present disclosure further provides an electronic apparatus including the semiconductor device described above. The electronic apparatus may further include a display screen, a wireless transceiver, or other components. Such electronic apparatus may be, for example, a smart phone, a personal computer (PC), a tablet computer, a wearable intelligence apparatus, an artificial intelligence apparatus, a mobile power supply, etc.

According to the embodiments of the present disclosure, a method of manufacturing a system-on-a-chip (SoC) is further provided. The method may include the methods mentioned above. Specifically, a variety of devices may be integrated on a chip, and at least some of the devices are manufactured according to the methods disclosed in the present disclosure.

In the above descriptions, the technical details such as patterning and etching of each layer have not been described in detail. However, those skilled in the art should understand that various technical means may be used to form layers, regions, etc. of desired shapes. In addition, in order to form the same structure, those skilled in the art may also design a method that is not completely the same as the method described above. In addition, although various embodiments are described above separately, this does not mean that the measures in the various embodiments may not be advantageously used in combination.

The embodiments of the present disclosure have been described above. However, these embodiments are just for illustrative purposes, and are not intended to limit the scope of the present disclosure. The scope of the present disclosure is defined by the appended claims and their equivalents. Those skilled in the art may make various substitutions and modifications without departing from the scope of the present disclosure, and these substitutions and modifications should all fall within the scope of the present disclosure.

What is claimed is:

1. A method of manufacturing a vertical device by firstly etching an active region of the device, comprising:
providing a stack of a first source/drain defining layer, a channel defining layer and a second source/drain defining layer on a substrate;
providing a mask layer on the stack;
providing a patterned photoresist on the stack, wherein the patterned photoresist exposes a first region;
etching off, in the first region, a first depth of the stack based on the patterned photoresist; and
further etching off, in the first region and a second region on an inner side of the first region, a second depth of the stack based on the mask layer, wherein the stack is penetrated by the etching off and the further etching off in the first region to form an isolation trench.

2. The method according to claim 1, wherein the providing a patterned photoresist comprises:
providing the patterned photoresist on the mask layer; and
wherein the etching off, in the first region, a first depth of the stack based on the patterned photoresist comprises:
etching the mask layer by using the patterned photoresist as an etching mask;
removing the photoresist; and
etching off, in the first region, the first depth of the stack by using an etched mask layer as an etching mask.

3. The method according to claim 1, wherein the providing a mask layer on the stack comprises:
providing a patterned mask layer on the stack, wherein the patterned mask layer exposes the first region and the second region;
wherein the providing a patterned photoresist comprises:
providing the patterned photoresist on the stack, wherein the patterned photoresist covers the patterned mask layer and exposes the first region; and
wherein the etching off, in the first region, a first depth of the stack based on the patterned photoresist comprises:
etching the stack by using the patterned photoresist as an etching mask.

4. The method according to claim 1, wherein the patterned photoresist is formed above an upper surface of the stack, so as to cover a height difference in the mask layer.

5. The method according to claim 2, wherein the patterned photoresist is formed above an upper surface of the stack, so as to cover a height difference in the mask layer.

6. The method according to claim 3, wherein the patterned photoresist is formed above an upper surface of the stack, so as to cover a height difference in the mask layer.

7. The method according to claim 2, wherein the providing a mask layer on the stack comprises:
forming an etching stop layer, a mandrel layer and an upper hard mask layer sequentially on the stack;
patterning the upper hard mask layer and the mandrel layer; and
forming a preparatory spacer layer in a substantially conformal manner on the etching stop layer; and
wherein the method further comprises:
performing an anisotropic etching on the preparatory spacer layer, so as to form a spacer on a sidewall of the mandrel layer, wherein the spacer and the mandrel layer expose the first region and the second region.

8. The method according to claim 3, wherein the providing a mask layer on the stack comprises:
forming an etching stop layer, a mandrel layer and an upper hard mask layer sequentially on the stack;
patterning the upper hard mask layer and the mandrel layer;
forming a preparatory spacer layer in a substantially conformal manner on the etching stop layer; and
performing an anisotropic etching on the preparatory spacer layer, so as to form a spacer on a sidewall of the mandrel layer, wherein the spacer and the mandrel layer expose the first region and the second region.

9. The method according to claim 1, further comprising:
selectively etching the channel defining layer, so that a sidewall of the channel defining layer is laterally recessed relative to a sidewall of the first source/drain defining layer and a sidewall of the second source/drain defining layer.

10. The method according to claim 2, further comprising:
selectively etching the channel defining layer, so that a sidewall of the channel defining layer is laterally recessed relative to a sidewall of the first source/drain defining layer and a sidewall of the second source/drain defining layer.

11. The method according to claim 3, further comprising:
selectively etching the channel defining layer, so that a sidewall of the channel defining layer is laterally recessed relative to a sidewall of the first source/drain defining layer and a sidewall of the second source/drain defining layer.

12. The method according to claim 9, further comprising:
forming an active layer on the first source/drain defining layer, the channel defining layer, the second source/drain defining layer and the substrate.

13. The method according to claim 9, further comprising:
forming a dielectric layer on the substrate;
etching the dielectric layer until the first source/drain defining layer is exposed; and
forming an active layer on the first source/drain defining layer, the channel defining layer and the second source/drain defining layer.

14. The method according to claim 1, wherein the first source/drain defining layer, the channel defining layer and the second source/drain defining layer are formed by epitaxy.

15. The method according to claim 2, wherein the first source/drain defining layer, the channel defining layer and the second source/drain defining layer are formed by epitaxy.

16. The method according to claim 3, wherein the first source/drain defining layer, the channel defining layer and the second source/drain defining layer are formed by epitaxy.
